(19) United States
(12) Patent Application Publication
(10) Pub. No.: US 2026/0282735 A1
(43) Pub. Date: Sep. 17, 2026

(54) PHOTOVOLTAIC DEVICE BASED ON SELF-ASSEMBLED TWO-DIMENSIONAL PEROVSKITE

(71) Applicant: EWHA UNIVERSITY-INDUSTRY COLLABORATION FOUNDATION, Seoul (KR)

(72) Inventors: William JO, Seoul (KR); Jihyun KIM, Seoul (KR)

(21) Appl. No.: 19/666,390

(22) Filed: May 4, 2026

Related U.S. Application Data
(63) Continuation of application No. PCT/KR2025/005091, filed on Apr. 15, 2025.

(30) Foreign Application Priority Data
May 2, 2024 (KR) 10-2024-0058294
Jan. 21, 2025 (KR) 10-2025-0008511

(51) Int. Cl. H10K 85/50; H10K 30/30; H10K 30/40; H10K 30/80

(52) U.S. Cl. CPC H10K 85/50; H10K 30/30; H10K 30/40; H10K 30/865

(57) ABSTRACT

The present disclosure relates to a photovoltaic device including a two-dimensional perovskite that is self-assembled between a perovskite and an electron transport layer, and to a method of fabricating the same. In a perovskite photovoltaic device according to embodiments of the present disclosure, a two-dimensional perovskite (as a non-limiting example, OA₂PbI₄) that is self-assembled between an electron transport layer and a perovskite layer removes defects such as oxygen vacancies formed on the surface of the electron transport layer, aligns a band structure at the interface between the electron transport layer and the perovskite layer, and provides a passivation effect for the perovskite. Accordingly, the device efficiency can be improved, and long-term stability can be enhanced.

### CROSS-REFERENCE TO RELATED APPLICATIONS

This application is a continuation of PCT Application No. PCT/KR2025/005091, filed on Apr. 15, 2025, which claims priorities to Korean Patent Applications No. 10-2024-0058294 filed on May 2, 2024, and No. 10-2025-0008511 filed on Jan. 21, 2025, all of which are hereby incorporated by reference in their entirety.

### TECHNICAL FIELD

The present disclosure relates to a photovoltaic device including a two-dimensional perovskite that is self-assembled between a perovskite and an electron transport layer, and to a method of fabricating the same.

### BACKGROUND

Metal halide perovskite solar cells have attracted attention due to the continuous improvement in power conversion efficiency (PCE), the utilization of cost-effective materials, and simple solution-based manufacturing processes. However, halide-based perovskites exhibit electron and ion conduction mainly due to iodine vacancies that cause unbalanced local stoichiometric variations. As a result, in narrow-bandgap perovskites, the perovskite material undergoes decomposition, and in wide-bandgap perovskites, phase separation occurs. Further, charge accumulation at the interface, which contributes to initial degradation, is affected by the electron transport layer (ETL) composed of oxide materials.

To solve these issues and improve the performance of solar cell devices, various passivation strategies for perovskites have been studied, ranging from the introduction of additives during precursor synthesis to interfacial passivation applied on or below the perovskite layer. Nevertheless, a problem remains in that certain passivation materials for solar cells may cause the accumulation of not only electronic charges but also ionic defects at the interface and bulk inhomogeneity, thereby becoming a major factor in the deterioration of device performance.

### PRIOR ART DOCUMENT

### Non-Patent Literature

Park, B. wook et al. Publisher Correction: Stabilization of formamidinium lead triiodide α-phase with isopropylammonium chloride for perovskite solar cells (Nature Energy, (2021), 6, 4, (419-428), 10.1038/s41560-021-00802-z). Nat. Energy 6, 848 (2021).

### DISCLOSURE OF THE INVENTION

### Problems to be Solved by the Invention

The present disclosure relates to a photovoltaic device including a two-dimensional perovskite that is self-assembled between a perovskite and an electron transport layer, and to a method of fabricating the same.

However, problems to be solved by the present disclosure are not limited to the above-described problems, and although not described herein, other problems to be solved by the present disclosure can be clearly understood bythose skilled in the art from the following descriptions.

### Means for Solving the Problems

A first aspect of the present disclosure provides a perovskite photovoltaic device, including: a first passivation layer including an ammonium salt; an electron transport layer formed on the first passivation layer and including a metal oxide; a perovskite layer formed on the electron transport layer; and a second passivation layer formed on the perovskite layer and including a compound represented by the following Chemical Formula 1, wherein a two-dimensional perovskite is included at an interface between the electron transport layer and the perovskite layer:

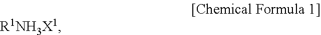

In Chemical Formula 1,

R¹ is a C₅₋₂₀ alkyl group, and X¹ is F, Cl, Br, or I.

A second aspect of the present disclosure provides a method of fabricating a perovskite photovoltaic device, including: forming a first passivation layer including an ammonium salt on a first electrode; forming an electron transport layer including a metal oxide on the first passivation layer; forming a perovskite layer on the electron transport layer; and forming a second passivation layer including a compound represented by the Chemical Formula 1 on the perovskite layer, wherein a two-dimensional perovskite is self-assembled at an interface between the electron transport layer and the perovskite layer.

### Effects of the Invention

In a perovskite photovoltaic device according to embodiments of the present disclosure, a two-dimensional perovskite (as a non-limiting example, OA₂PbI₄) that is self-assembled between an electron transport layer and a perovskite layer removes defects such as oxygen vacancies formed on the surface of the electron transport layer, aligns a band structure at the interface between the electron transport layer and the perovskite layer, and provides a passivation effect for the perovskite. Accordingly, the device efficiency can be improved, and long-term stability can be enhanced.

### BRIEF DESCRIPTION OF THE DRAWINGS

FIG. 1 is a schematic diagram illustrating the structure of perovskite photovoltaic devices (M1, M2 and M3) according to an example of the present disclosure.

FIGS. 2A, 2B, and 2C schematically illustrate ions formed during the passivation of the SnO₂ electron transport layers of M1, M2, and M3 according to an example of the present disclosure.

FIGS. 3A and 3B illustrate schematic diagrams showing the formation of a two-dimensional OA₂PbI₄ perovskite via the diffusion of OA⁺ and NH₄⁺ (FIG. 3A) and a migration barrier value of NH₄⁺ obtained through computational simulations (FIG. 3B) according to an example of the present disclosure.

FIGS. 4A(i), 4B(i), and 4C(i) show cross-sectional schematic diagrams of M1, M2, and M3; and FIGS. 4A(ii), 4B(ii), and 4C(ii) show the results of C 1s X-ray photoelectron spectroscopy (XPS) measurements at the interface between an SnO₂ electron transport layer and a perovskite layer of M1, M2, and M3, according to an example of the present disclosure.

FIGS. 5A(i)-5A(iii), FIGS. 5B(i)-5B(iii), and FIGS. 5C(i)-5C(iii) respectively show the results of cross-sectional transmission electron microscopy (TEM) measurements for M3, M2, and M1 according to an example of the present disclosure.

FIGS. 6A, 6B, and 6C show the results of photoluminescence measurements at the interface between the SnO₂ electron transport layer and the perovskite layer of M1, M2, and M3 according to an example of the present disclosure.

FIGS. 7A-7F show the results of scanning electron microscopy (SEM) measurements at the perovskite surface of M1, M2, and M3 according to an example of the present disclosure.

FIGS. 8A(i), 8A(ii), 8B(i), 8B(ii), 8C(i), and 8C(ii) show the results of X-ray diffraction (XRD) measurements at the perovskite surface of M1, M2, and M3 according to an example of the present disclosure.

FIGS. 9A and 9B show the results of time-of-flight secondary ion mass spectrometry (TOF-SIMS) measurements for M1 and M2 according to an example of the present disclosure.

FIGS. 10A(i), 10A(ii), 10B(i), 10B(ii), 10C(i), and 10C(ii) show the evaluation results of the photovoltaic device characteristics of M1, M2, and M3 according to an example of the present disclosure.

FIG. 11 shows the evaluation results of the long-term stability of the photovoltaic devices M1, M2, and M3 according to an example of the present disclosure.

### BEST MODE FOR CARRYING OUT THE INVENTION

Hereinafter, embodiments and examples of the present disclosure will be described in detail with reference to the accompanying drawings so that the present disclosure may be readily implemented by those skilled in the art. However, it is to be noted that the present disclosure is not limited to the embodiments and examples but can be embodied in various other ways. In drawings, parts irrelevant to the description are omitted for the simplicity of explanation, and like reference numerals denote like parts through the whole document.

Through the whole document, the term “connected to” or “coupled to” that is used to designate a connection or coupling of one element to another element includes both a case that an element is “directly connected or coupled to” another element and a case that an element is “electronically connected or coupled to” another element via still another element.

Through the whole document, the term “on” that is used to designate a position of one element with respect to another element includes both a case that the one element is adjacent to the other element and a case that any other element exists between these two elements.

Further, through the whole document, the term “comprises or includes” and/or “comprising or including” used in the document means that one or more other components, steps, operation and/or existence or addition of elements are not excluded in addition to the described components, steps, operation and/or elements unless context dictates otherwise.

Through the whole document, the term “about or approximately” or “substantially” is intended to have meanings close to numerical values or ranges specified with an allowable error and intended to prevent accurate or absolute numerical values disclosed for understanding of the present disclosure from being illegally or unfairly used by any unconscionable third party.

Through the whole document, the term “step of” does not mean “step for”.

Through the whole document, the term “combination(s) of” included in Markush type description means mixture or combination of one or more components, steps, operations and/or elements selected from a group consisting of components, steps, operation and/or elements described in Markush type and thereby means that the disclosure includes one or more components, steps, operations and/or elements selected from the Markush group.

Through the whole document, a phrase in the form “A and/or B” means “A or B, or A and B”.

Through the whole document, the term “alkyl” or “alkyl group” may individually include linear or branched alkyl groups having 1 to 12 carbon atoms, 1 to 10 carbon atoms, 1 to 8 carbon atoms, or 1 to 5 carbon atoms, and all the possible isomers thereof. For example, the alkyl or alkyl group may individually include methyl group (Me), ethyl group (Et), n-propyl group (ⁿPr), isopropyl group (ⁱPr), n-butyl group (ⁿBu), iso-butyl group (ⁱBu), tert-butyl group (^{t}Bu), sec-butyl group (^{s}Bu), n-pentyl group (ⁿPe), iso-pentyl group (ⁱPe), sec-pentyl group (^{s}Pe), tert-pentyl group (^{t}Pe), n-hexyl group, iso-hexyl group, heptyl group, 4,4-dimethyl pentyl group, octyl group, 2,2,4-trimethyl pentyl group, nonyl group, decyl group, undecyl group, dodecyl group, and isomers thereof, but may not be limited thereto.

In the following description, exemplary embodiments of the present disclosure will be described in detail, but the present disclosure may not be limited thereto.

A first aspect of the present disclosure provides a perovskite photovoltaic device, including: a first passivation layer including an ammonium salt; an electron transport layer formed on the first passivation layer and including a metal oxide; a perovskite layer formed on the electron transport layer; and a second passivation layer formed on the perovskite layer and including a compound represented by the following Chemical Formula 1, wherein a two-dimensional perovskite is included at an interface between the electron transport layer and the perovskite layer:

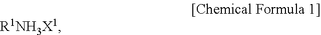

In Chemical Formula 1, R¹ is a C₅₋₂₀ alkyl group, and X¹ is F, Cl, Br, or I.

In an embodiment of the present disclosure, the ammonium salt may include at least one selected from NH₄Cl (ammonium chloride), NH₄Br (ammonium bromide), NH₄I (ammonium iodide), NH₄F (ammonium fluoride), NH₄NO₃ (ammonium nitrate), (NH₄)₂CO₃ (ammonium carbonate), NH₄HCO₃ (ammonium bicarbonate), (NH₄)₂SO₄ (ammonium sulfate), (NH₄)₂S₂O₃(ammonium persulfate), NH₄HSO₃ (ammonium bisulfite), NH₄HSO₄ (ammonium bisulfate), NH₄ClO₄ (ammonium perchlorate), CH₃COONH₄ (ammonium acetate), C₆H₅COONH₄ (ammonium benzoate), NH₄H₂PO₄ (ammonium dihydrogen phosphate), (NH₄)₂HPO₄ (diammonium hydrogen phosphate), NH₄SCN (ammonium thiocyanate), NH₄BF₄ (ammonium tetrafluoroborate), and NH₄PF₆ (ammonium hexafluorophosphate), but may not be limited thereto.

In an embodiment of the present disclosure, the two-dimensional perovskite may be formed through self-assembly.

In an embodiment of the present disclosure, the perovskite may be represented by the following Chemical Formula 2, but may not be limited thereto:

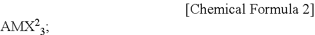

In Chemical Formula 2, A may be a monovalent cation, an organic ammonium ion, an organic amidinium ion, a guanidinium ion, an organic phosphonium ion, an alkali metal ion, or a combination or derivative thereof, M may be a metal, a transition metal, a rare earth metal, an alkaline earth metal, an organic substance, an inorganic substance, ammonium, or a combination or derivative thereof, and X² may be a halogen ion selected from F, Cl, Br, or I.

In an embodiment of the present disclosure, in Chemical Formula 2, A may be methylammonium ion, formamidinium ion, acetamidinium ion, or guanidinium ion, but may not be limited thereto.

In an embodiment of the present disclosure, in Chemical Formula 2, M may be Pb, Sn, Cu, Ni, Co, Fe, Mn, Pd, Cd, Ge, Cs, Eu, or a combination thereof, but may not be limited thereto.

In an embodiment of the present disclosure, X¹ in Chemical Formula 1 may be the same as X² in Chemical Formula 2.

In an embodiment of the present disclosure, the two-dimensional perovskite may include a compound represented by the following Chemical Formula 3:

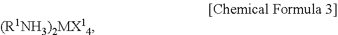

In Chemical Formula 3, R¹ may be a C₅₋₂₀ alkyl group, M may be Pb, Sn, Cu, Ni, Co, Fe, Mn, Pd, Cd, Ge, Cs, Eu, or a combination thereof, and X¹ may be F, Cl, Br, or I.

In an embodiment of the present disclosure, in Chemical Formula 1 or 3, R¹ may be a C₅₋₂₀ alkyl group, a C₅₋₁₅ alkyl group, a C₅₋₁₄ alkyl group, a C₅₋₁₃ alkyl group, a C₅₋₁₂ alkyl group, a C₅₋₁₁ alkyl group, a C₅₋₁₀ alkyl group, a C₆₋₂₀ alkyl group, a C₆₋₁₅ alkyl group, a C₆₋₁₄ alkyl group, a C₆₋₁₃ alkyl group, a C₆₋₁₂ alkyl group, a C₆₋₁₁ alkyl group, or a C₆₋₁₀ alkyl group.

In an embodiment of the present disclosure, the two-dimensional perovskite may include OA₂PbI₄.

In an embodiment of the present disclosure, the metal oxide may include at least one selected from SnO₂, TiO₂, ZnO, WO₃, RuO₂, LaₓSr₁₋ₓCoO₃, LaₓSr₁₋ₓMnO₃, BaSnO₃ and LaNiO₃, wherein 0<x≤0.5, but may not be limited thereto.

In an embodiment of the present disclosure, the first passivation layer is formed prior to the formation of the electron transport layer, and the formation of the first passivation layer may be referred to as pretreatment passivation of the electron transport layer.

In an embodiment of the present disclosure, NH₄⁺ ions may diffuse from the first passivation layer and may be present on the surface of the electron transport layer.

In an embodiment of the present disclosure, R¹NH₃⁺ ions (as a non-limiting example, OA⁺ (octylammonium) ions) and halogen ions may diffuse from the second passivation layer and may be present on an upper surface of the electron transport layer (i.e., a surface contacting the perovskite layer). In this case, the NH₄⁺ ions present on the surface of the electron transport layer may be substituted with the R¹NH₃⁺ ions, thereby forming a two-dimensional perovskite at the interface between the electron transport layer and the perovskite layer. More specifically, for example, when the perovskite layer contains FAPbI₃ and the compound represented by Chemical Formula 1 is OAI (octylammonium iodide), the formation of the FAPbI₃ perovskite layer on the surface of the electron transport layer where NH₄⁺ ions are present results in the formation of intermediate phase (metaphase) NH₄PbI₃ at the interface. Since the migration barrier of NH₄⁺ is low, NH₄⁺ from NH₄PbI₃ diffuses into the perovskite layer, and OA⁺ present on an upper surface of the perovskite layer diffuses toward the surface of the electron transport layer. Thus, NH₄⁺ is substituted with OA⁺, resulting in a two-dimensional OA₂PbI₄ perovskite formed at the interface.

In an embodiment of the present disclosure, the two-dimensional perovskite may be present as a mixture with a three-dimensional perovskite.

In an embodiment of the present disclosure, a two-dimensional-three-dimensional perovskite layer containing the two-dimensional perovskite and the three-dimensional perovskite may be formed at the interface between the electron transport layer and the perovskite layer.

In an embodiment of the present disclosure, the two-dimensional perovskite may serve as a passivation layer, similar to the first and second passivation layers.

In an embodiment of the present disclosure, the two-dimensional perovskite may passivate defects, such as oxygen vacancies generated on the surface of the electron transport layer, and may improve charge transfer from the perovskite layer to the electron transport layer, thereby improving device efficiency.

In an embodiment of the present disclosure, the two-dimensional perovskite may improve charge transport by aligning the band structure at the interface between the electron transport layer and the perovskite layer. A conventional passivation method for the electron transport layer is a post-treatment process conducted after the formation of the electron transport layer. Therefore, it is difficult to align a band structure at the interface between the perovskite layer and the electron transport layer. The two-dimensional perovskite of the present disclosure is stabilized in a self-assembled form at the interface between the electron transport layer and the perovskite layer, and may align the band structure without artificially altering the band structure.

In an embodiment of the present disclosure, the two-dimensional perovskite may provide a lower-side passivation effect for the perovskite layer, while the second passivation layer may provide an upper-side passivation effect for the perovskite layer. Accordingly, the perovskite layer may exhibit improved efficiency and efficiency stability through dual-side passivation.

In an embodiment of the present disclosure, a C 1s X-ray photoelectron spectroscopy (XPS) spectrum at the interface between the electron transport layer and the perovskite layer may exhibit a peak in the range of about 291 eV to about 294 eV due to the two-dimensional perovskite layer (as a non-limiting example, OA₂PbI₄).

In an embodiment of the present disclosure, a photoluminescence (PL) spectrum at the interface between the electron transport layer and the perovskite layer may exhibit a peak at about 520 nm to about 530 nm due to the two-dimensional perovskite layer (as a non-limiting example, OA₂PbI₄).

In an embodiment of the present disclosure, the perovskite photovoltaic device may maintain a power conversion efficiency of about 90% or more, about 91% or more, or about 92% or more even after about 2,000 hours.

In an embodiment of the present disclosure, the perovskite photovoltaic device may further include a substrate, a first electrode, a hole transport layer, and/or a second electrode.

In an embodiment of the present disclosure, the substrate, the first electrode, the hole transport layer, and the second electrode may be selected without limitation as long as they are commonly used in photovoltaic devices. As non-limiting examples, the substrate may contain glass or a transparent polymer. The first electrode may be a transparent electrode, and may contain, as a non-limiting example, ITO (indium tin oxide), IZO (In—ZnO), GZO (Ga—ZnO), AZO (AI-ZnO), AGZO (Al—Ga ZnO), IGZO (In—Ga ZnO), or FTO (fluorine-doped tin oxide). The hole transport layer may contain, as a non-limiting example, Spiro-OMeTAD.

In an embodiment of the present disclosure, the perovskite photovoltaic device may include: the first electrode formed on the substrate; the first passivation layer formed on the first electrode and including NH₄Cl; the electron transport layer formed on the first passivation layer and including a metal oxide; the perovskite layer formed on the electron transport layer; the second passivation layer formed on the perovskite layer and including OAI (octylammonium iodide); the hole transport layer formed on the second passivation layer; and the second electrode formed on the hole transport layer.

A second aspect of the present disclosure provides a method of fabricating a perovskite photovoltaic device, including: forming a first passivation layer including an ammonium salt on a first electrode; forming an electron transport layer including a metal oxide on the first passivation layer; forming a perovskite layer on the electron transport layer; and forming a second passivation layer including a compound represented by the following Chemical Formula 1 on the perovskite layer, wherein a two-dimensional perovskite is self-assembled at an interface between the electron transport layer and the perovskite layer:

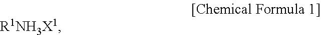

In Chemical Formula 1,

R¹ is a C₅₋₂₀ alkyl group, and X¹ is F, Cl, Br, or I.

Detailed descriptions of parts of the second aspect, which overlap with those of the first aspect, are omitted hereinafter, but the descriptions of the first aspect of the present disclosure may be identically applied to the second aspect of the present disclosure, even though they are omitted hereinafter.

In an embodiment of the present disclosure, the two-dimensional perovskite may include a compound represented by the following Chemical Formula 3:

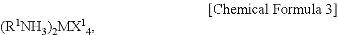

In Chemical Formula 3,

R¹ may be a C₅₋₂₀ alkyl group, M may be Pb, Sn, Cu, Ni, Co, Fe, Mn, Pd, Cd, Ge, Cs, Eu, or a combination thereof, and X¹ may be F, Cl, Br, or I.

In an embodiment of the present disclosure, the two-dimensional perovskite may include OA₂PbI₄.

In an embodiment of the present disclosure, the metal oxide may include at least one selected from SnO₂, TiO₂, ZnO, WO₃, RuO₂, LaₓSr₁₋ₓCoO₃, LaₓSr₁₋ₓMnO₃, BaSnO₃ and LaNiO₃, wherein 0<x≤0.5.

In an embodiment of the present disclosure, the process of forming the first passivation layer may include a process of applying a first passivation solution including the ammonium salt, but is not limited thereto.

In an embodiment of the present disclosure, the concentration of the ammonium salt in the first passivation solution is about 1 mM to about 1,000 mM, but is not limited thereto. In an embodiment of the present disclosure, the concentration of the ammonium salt in the first passivation solution is about 1 mM to about 1,000 mM, about 1 mM to about 100 mM, about 1 mM to about 50 mM, about 1 mM to about 40 mM, about 10 mM to about 1,000 mM, about 10 mM to about 100 mM, about 10 mM to about 50 mM, about 10 mM to about 40 mM, about 30 mM to about 1,000 mM, about 30 mM to about 100 mM, about 30 mM to about 50 mM, about 30 mM to about 40 mM, about 35 mM to about 1,000 mM, about 35 mM to about 100 mM, about 35 mM to about 50 mM, or about 35 mM to about 40 mM, but is not limited thereto.

In an embodiment of the present disclosure, the process of forming the second passivation layer may include a process of applying a second passivation solution including the compound represented by Chemical Formula 1, but is not limited thereto.

In an embodiment of the present disclosure, the concentration of the compound represented by Chemical Formula 1 in the second passivation solution may be about 1 mM to about 1,000 mM, but is not limited thereto.

In an embodiment of the present disclosure, the concentration of the compound represented by Chemical Formula 1 in the second passivation solution may be about 1 mM to about 1,000 mM, about 1 mM to about 100 mM, about 1 mM to about 50 mM, about 1 mM to about 30 mM, about 1 mM to about 20 mM, about 10 mM to about 1,000 mM, about 10 mM to about 100 mM, about 10 mM to about 50 mM, about 10 mM to about 30 mM, about 10 mM to about 20 mM, about 15 mM to about 1,000 mM, about 15 mM to about 100 mM, about 15 mM to about 50 mM, about 15 mM to about 30 mM, or about 15 mM to about 20 mM, but is not limited thereto.

In an embodiment of the present disclosure, the application may be performed through a solution process. Non-limiting examples of the solution process may include spin-coating, dip-coating, spin-casting, or spraying.

In an embodiment of the present disclosure, after the first passivation layer, the electron transport layer, the perovskite layer, and the second passivation layer are formed, each layer may be further heat-treated for curing.

In an embodiment of the present disclosure, the heat treatment may be performed at a temperature of about 50° C. to about 300° C. for about 5 minutes to about 100 minutes, but is not limited thereto.

In an embodiment of the present disclosure, after the first passivation layer, the electron transport layer, and the second passivation layer are formed, each layer may be further subjected to UV-ozone treatment.

In an embodiment of the present disclosure, the UV-ozone treatment may be performed for about 1 minute to about 100 minutes, about 1 minute to about 60 minutes, about 1 minute to about 30 minutes, about 1 minute to about 20 minutes, about 1 minute to about 10 minutes, about 5 minutes to about 100 minutes, about 5 minutes to about 60 minutes, about 5 minutes to about 30 minutes, about 5 minutes to about 20 minutes, or about 5 minutes to about 10 minutes, but is not limited thereto.

Hereinafter, the present disclosure will be described in more detail with reference to Examples, but the present disclosure may not be limited thereto.

### MODE FOR CARRYING OUT THE INVENTION

### Examples

### 1) Fabrication of Device

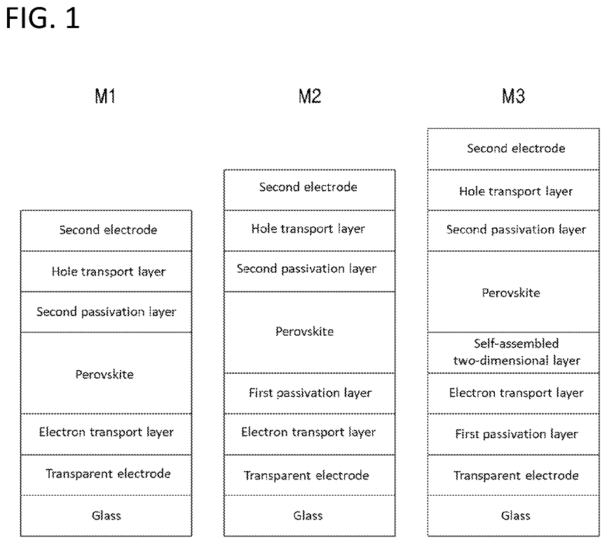

Perovskite photovoltaic devices having three structures, M1, M2, and M3, were fabricated based on the application of passivation layers (FIG. 1).

### 1) Formation and Passivation Treatment of SnO₂ Electron Transport Layer

An SnO₂ solution was prepared by mixing an SnO₂ nanoparticle solution with deionized water. Further, an NH₄Cl passivation solution having a concentration of 37.4 mM was prepared by dissolving NH₄Cl powder in ethanol. After cleaning a glass/ITO (indium tin oxide) substrate, UV-ozone treatment was performed thereon for 20 minutes. For fabrication of M1, 200 μL of the SnO₂ solution was applied onto the glass/ITO substrate and spin-coated at 4,000 rpm for 30 seconds, followed by heat treatment on a hot plate at 150° C. for 30 minutes to form an SnO₂ thin film. For fabrication of M2, an SnO₂ thin film was formed on a glass/ITO substrate in the same manner as described above, and then UV-ozone treatment was performed for 20 minutes. Thereafter, 150 μL of the NH₄Cl solution was applied onto the SnO₂ thin film and spin-coated at 5,000 rpm for 20 seconds, followed by heat treatment on a hot plate at 70° C. for 10 minutes to form an NH₄Cl thin film. For fabrication of M3, an NH₄Cl thin film was formed on a glass/ITO substrate in the same manner as described above, and then UV-ozone treatment was performed for 10 minutes. Thereafter, an SnO₂ thin film was formed on the NH₄Cl thin film in the same manner as described above.

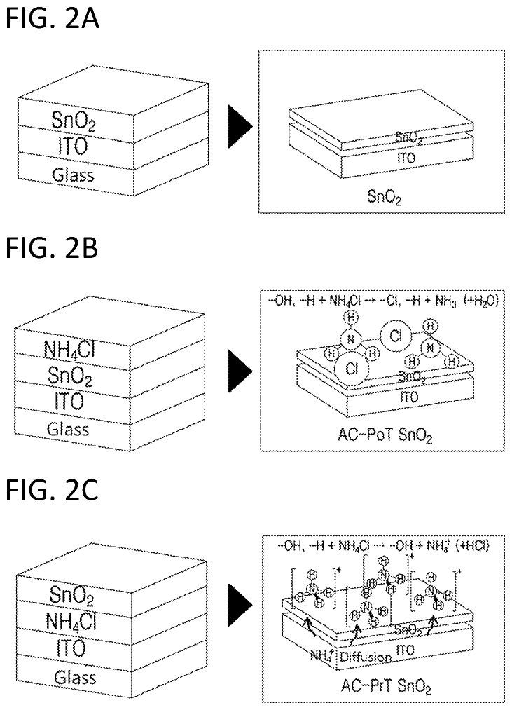

FIG. 2A, FIG. 2B, and FIG. 2C schematically illustrate ions formed on SnO₂ electron transport layers during the passivation of the SnO₂ electron transport layers.

### 2) Formation and Passivation Treatment of Perovskite Layer

### Synthesis of Formamidinium Iodide (FAI)

After 15 g of formamidine acetate (FA acetate) powder was placed in a round-bottom flask, the flask was positioned in an ice bath. Then, 40 mL of hydroiodic acid (HI) was slowly added to the mixture with stirring for 2 hours. Thereafter, the HI solvent was removed using a rotary evaporator under a controlled vacuum at 65° C., thereby obtaining yellow and white precipitates. The precipitates were washed several times with ether until the powder became pure white. The white precipitates were dissolved in ethanol and recrystallized by adding ether. This process was repeated twice. Finally, FAI powder was obtained and dried in a vacuum oven for 24 hours.

### Synthesis of FAPbI₃ Single Crystal

FAI powder (1.5 M) and PbI₂ powder (1.5 M) were dissolved in a gamma-butyrolactone (GBL) solution for 24 hours. After filtering through a 0.2 μm filter, single crystals were grown on a 120° C. hot plate for 3 hours. The obtained black FAPbI₃ single crystals were washed with acetonitrile and then with ether. The washed single crystals were dried on a 150° C. hot plate for 30 minutes.

### Preparation of Perovskite Precursor

DMF (N,N-dimethylformamide) and DMSO (dimethyl sulfoxide) were mixed at a volume ratio of 8:1. FAPbI₃ single crystals and MACI (methylammonium chloride) (20 mol %) were dissolved in the mixed solution to a concentration of 1.6 M each, thereby preparing a perovskite precursor solution.

### Formation and Passivation Treatment of Perovskite Layer

70 μL of a perovskite precursor solution was applied onto an SnO₂ electron transport layer and spin-coated at 4,000 rpm for 25 seconds. During spin-coating, 800 μL of ether was dropped 10 seconds before the end of the spin-coating process to remove the solvent. Thereafter, the spin-coated thin film was heat-treated on a 150° C. hot plate for 10 minutes. A perovskite passivation solution was prepared by dissolving 0.0193 g of OAI (n-octylammonium iodide) in 5 mL of IPA (isopropyl alcohol), thereby obtaining a 15 mM OAI solution. After the OAI solution was applied onto the surface of the perovskite thin film, spin-coating was performed at 3,000 rpm for 30 seconds to form a passivation layer.

### 3) Formation of Hole Transport Layer and Electrode

A hole transport layer (HTL) was formed using a spiro-OMeTAD solution composed of 72.3 mg of spiro-OMeTAD powder dissolved in 1 mL of chlorobenzene, together with a stock solution of 30 μL of tBP(4-tert-butylpyridine) and 35 μL of Li-TFSI(lithium bis(trifluoromethanesulfonyl)imide). After the HTL solution was applied onto the perovskite layer, spin-coating was performed at 3,000 rpm for 25 seconds. Thereafter, a 100-nm-thick gold electrode was formed by thermal evaporation.

### 2. Result and Analysis

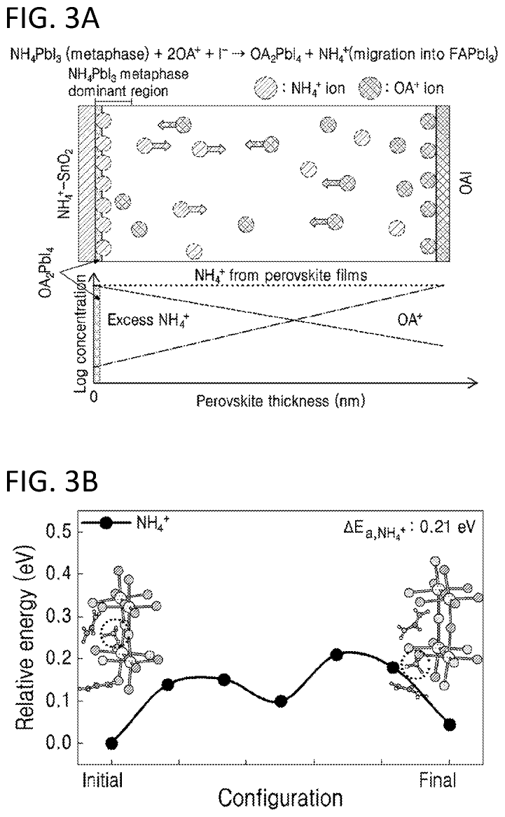

When an FAPbI₃ perovskite layer is formed on the surface of the electron transport layer on which NH₄⁺ is present, an intermediate phase (metaphase) NH₄PbI₃ is generated at the interface. Since a migration barrier of NH₄⁺ is low, NH₄⁺ from NH₄PbI₃ diffuses into the perovskite layer, and OA⁺ present on an upper surface of the perovskite layer diffuses toward the surface of the electron transport layer (SnO₂). As NH₄⁺ is substituted with OA⁺, a two-dimensional OA₂PbI₄ can be formed at the interface between the electron transport layer and the perovskite layer. FIG. 3A illustrates a schematic diagram showing the formation of a two-dimensional OA₂PbI₄ perovskite via the diffusion of OA⁺ and NH₄⁺. FIG. 3B shows a migration barrier value of NH₄⁺ obtained through computational simulations. Due to a low migration barrier value of 0.21 eV, NH₄⁺ can readily migrate into FAPbI₃.

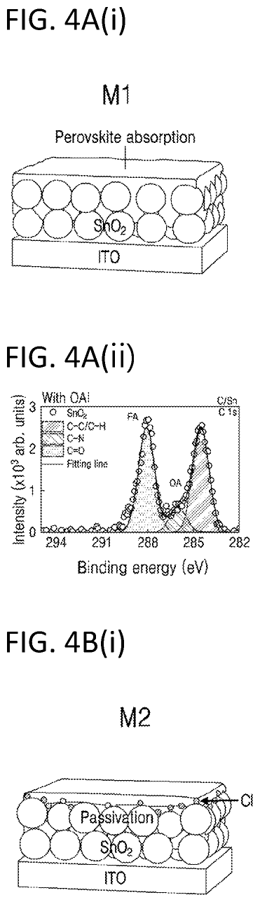

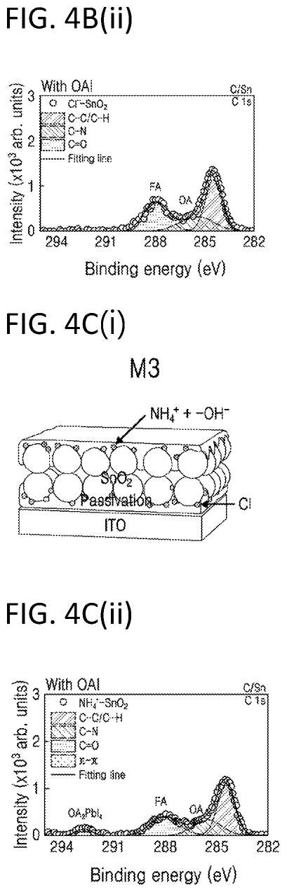

FIGS. 4A(i), 4B(i), and 4C(i) show cross-sectional schematic diagrams of M1, M2, and M3; and FIGS. 4A(ii), 4B(ii), and 4C(ii) show the results of C 1s X-ray photoelectron spectroscopy (XPS) measurements at the interface between an SnO₂ electron transport layer and a perovskite layer of M1, M2, and M3. The formation of a two-dimensional OA₂PbI₄ perovskite phase in M3 was observed from a peak near 292 eV. No OA₂PbI₄-related peak was observed in M1 or M2.

Table 1 below shows the XPS peak positions of FIGS. 4A(ii), 4B(ii), and 4C(ii).

TABLE 1

| | | C—C/C—H | C—N (OA) | C═O (FA) | π-π (OA₂Pbl₄) |
|---|---|---|---|---|---|
| M1 | Peak | 284.50553 | 286.0116 | 288.0671 | N/A |
| | position | | | | |
| | FWHM | 1.26356 | 1.26602 | 1.27248 | N/A |
| | Area | 3358.40806 | 796.43223 | 3388.92335 | N/A |
| M2 | Peak | 284.44447 | 285.4593 | 287.97594 | N/A |
| | position | | | | |
| | FWHM | 1.19661 | 2.547 | 1.70696 | N/A |
| | Area | 1443.02752 | 857.13312 | 1144.13754 | N/A |
| M3 | Peak | 284.42466 | 285.53015 | 288.02152 | 292.72505 |
| | position | | | | |
| | FWHM | 1.19719 | 1.93996 | 1.9631 | 1.01751 |
| | Area | 1343.9583 | 669.76246 | 830.48344 | 150.69262 |

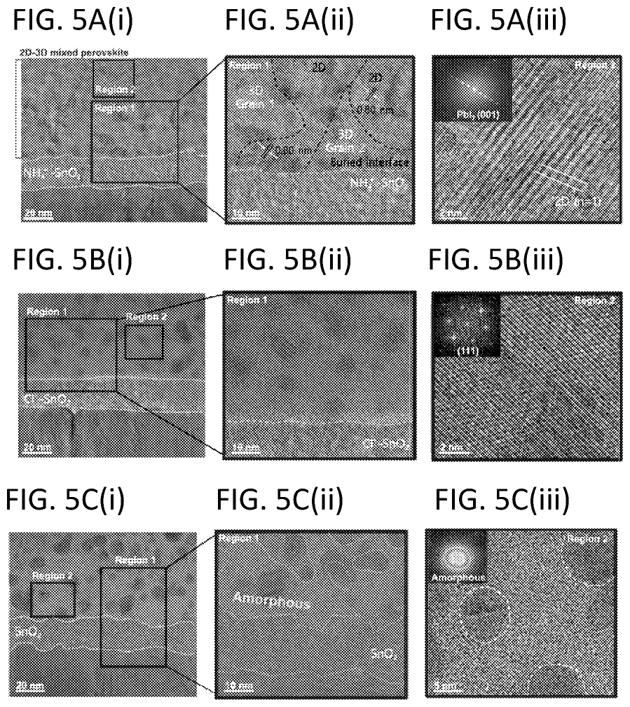

FIGS. 5A(i) to 5A(iii), FIGS. 5B(i) to 5B(iii), and FIGS. 5C(i) to 5C(iii) are cross-sectional transmission electron microscopy (TEM) images of M3, M2, and M1, respectively. Referring to FIGS. 5A(i) to 5A(iii), a self-assembled 2D-OA₂PbI₄ (n=1) structure can be observed near the NH₄⁺—SnO₂ interface in M3, indicating that the 2D-OA₂PbI₄ (n=1) structure is mixed with a three-dimensional (3D) perovskite structure. The 2D perovskite is formed between 3D perovskite structures, thereby generating a 2D-3D mixed perovskite phase at the buried interface. In particular, the mixed 2D-3D perovskite phase is formed near the NH₄⁺—SnO₂ buried interface through the diffusion of OA⁺ cations and a subsequent reaction with the pre-existing metaphase NH₄PbI₃ structure. An interlayer spacing of the 2D-OA₂PbI₄ lattice relative to the PbI₂ (001) plane was measured to be 0.8 nm, which is larger than an interlayer spacing of a typical 3D perovskite structure due to the large size of the OA⁺ cation. Referring to FIGS. 5B(i) to 5B(iii) and FIGS. 5C(i) to 5C(iii), the formation of 2D perovskite was not observed at the buried interfaces of M2 and M1. In M1, an amorphous phase was detected near the SnO₂ interface. This suggests that rapid absorption of water and oxygen may provide a fast decomposition pathway for perovskite solar cells. The observations from FIG. 5A(i) to FIG. 5C(iii) provide key evidence supporting the formation of the 2D-3D mixed perovskite phase at the NH₄⁺—SnO₂ interface and the resulting improvement in solar-cell stability and performance.

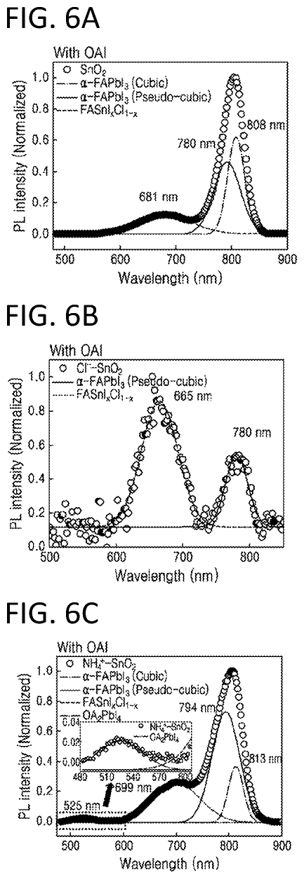

FIGS. 6A, 6B, and 6C show the results of photoluminescence (PL) measurements at the interface between SnO₂ and perovskite of M1, M2, and M3. In M3, the formation of a two-dimensional OA₂PbI₄ perovskite was observed from an emission peak near 525 nm. No OA₂PbI₄-related peak was observed in M1 or M2.

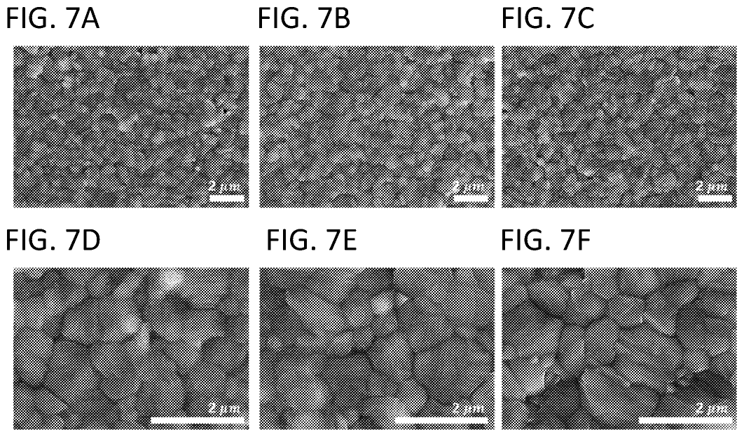

FIGS. 7A to 7F show the results of scanning electron microscopy (SEM) measurements at the perovskite surface of M1, M2, and M3. The perovskite crystallinity in M3 is more distinct.

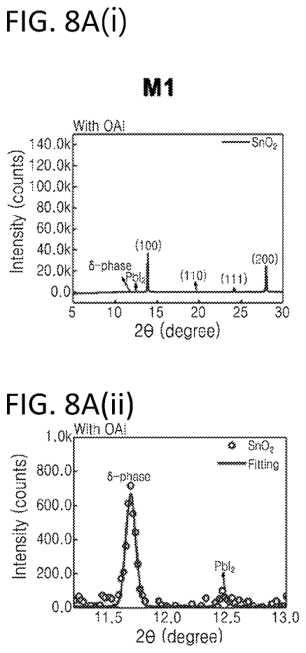

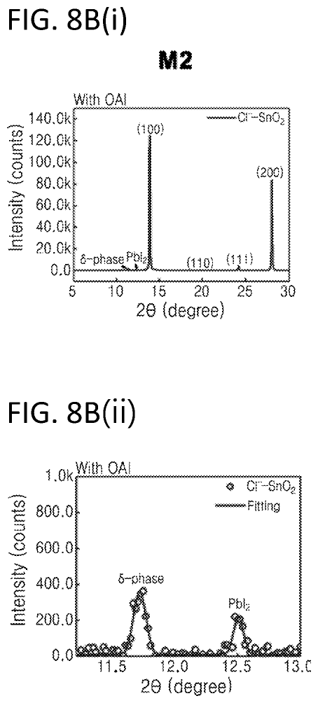

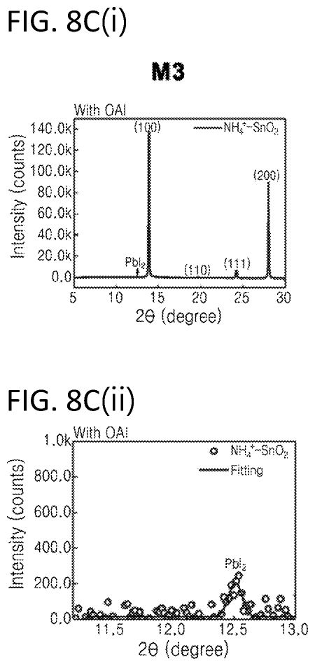

FIGS. 8A(i), 8A(ii), 8B(i), 8B(ii), 8C(i), and 8C(ii) show the results of X-ray diffraction (XRD) measurements at the perovskite surface of M1, M2, and M3. The crystallinity of M2 and M3 in all orientations was improved compared to M1, and the highest crystallinity was observed in M3. These results indicate that interfacial modification between SnO₂ and perovskite affects the perovskite surface. In particular, the non-perovskite delta phase disappears in M3. This is because, after NH₄⁺ from NH₄PbI₃, which exists between the electron transport layer and the perovskite layer, is substituted with OA⁺, the remaining NH₄⁺ diffuses into the perovskite layer due to its low migration barrier, and the diffused NH₄⁺ removes defects inside the perovskite layer, thereby suppressing delta-phase formation.

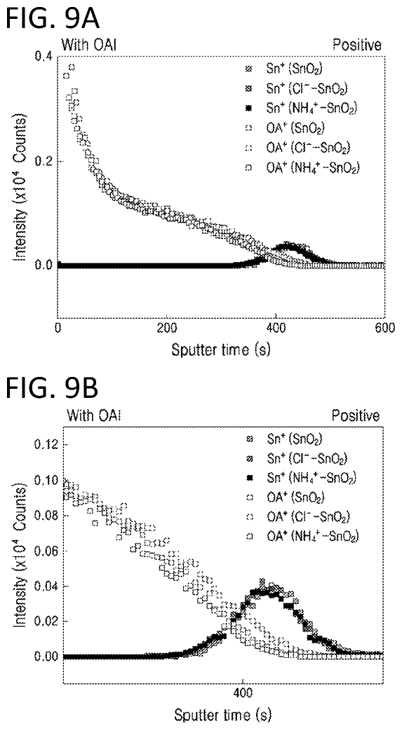

FIGS. 9A and 9B show the results of time-of-flight secondary ion mass spectrometry (TOF-SIMS) measurements for M1 and M2. From these results, migration of OA⁺ from the upper perovskite region toward the interface between SnO₂ and perovskite was confirmed.

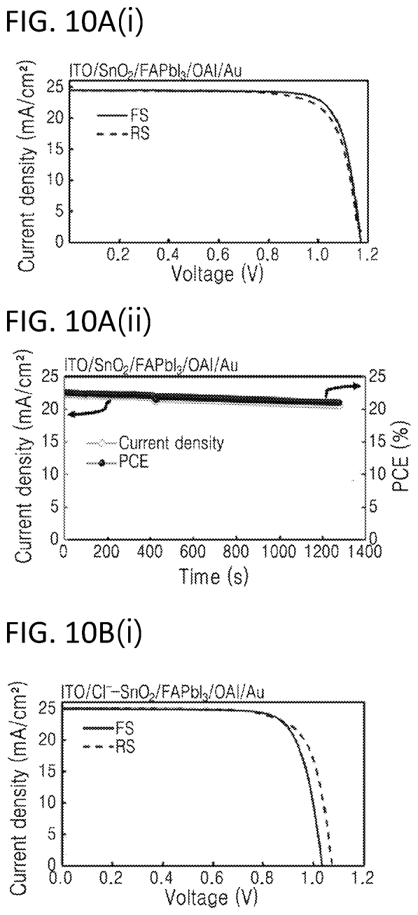

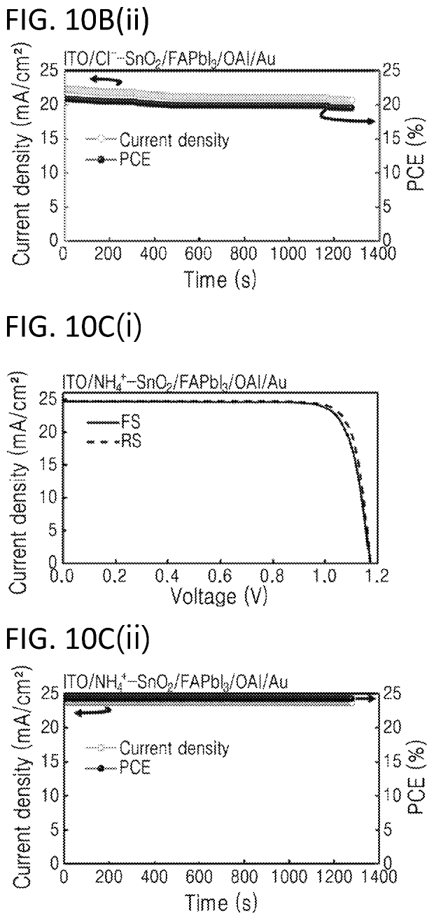

FIGS. 10A(i), 10A(ii), 10B(i), 10B(ii), 10C(i), and 10C(ii) show the evaluation results of the photovoltaic device characteristics of M1 (10A(i), 10A(ii)), M2 (10B(i), 10B(ii)), and M3 (10C(i), 10C(ii)). FIGS. 10A(i), 10B(i), and 10C(i) show current-voltage curves, where the solid and dotted lines represent forward scan (FS) and reverse scan (RS) results, respectively. Tables 2, 3, and 4 below summarize the photovoltaic device characteristics of M1, M2, and M3, respectively. A power conversion efficiency (PCE) value of M3 was 23.78%, which is the highest compared to M1 (22.97%) and M2 (20.15%). Further, M3 exhibited the highest device stability. FIGS. 10A(ii), 10B(ii), and 10C(ii) show the current density and PCE as a function of time. For M1 measured at Vₘₐₓ=1.01 V, the initial values were J_{Vmax}=22.32 mA/cm² and PCE=22.53%, and the final values were J_{Vmax}=20.53 mA/cm² and PCE=21.01%. For M2 measured at Vₘₐₓ=0.910 V, the initial values were J_{Vmax}=22.33 mA/cm² and PCE=20.91%, and the final values were J_{Vmax}=20.68 mA/cm² and PCE=19.50%. For M3 measured at Vₘₐₓ=1.03 V, the initial values were J_{Vmax}=23.73 mA/cm² and PCE=24.32%, and the final values were J_{Vmax}=23.72 mA/cm² and PCE=24.31%.

TABLE 2

| | PCE (%) | V_{OC} (V) | FF | J_{SC} (mA/cm²) |
|---|---|---|---|---|
| FS | 22.97 | 1.170 | 0.802 | 24.48 |
| RS | 21.96 | 1.165 | 0.769 | 24.51 |

TABLE 3

| | PCE (%) | V_{OC} (V) | FF | J_{SC} (mA/cm²) |
|---|---|---|---|---|
| FS | 20.15 | 1.037 | 0.778 | 24.98 |
| RS | 20.30 | 1.074 | 0.756 | 25.01 |

TABLE 4

| | PCE (%) | V_{OC} (V) | FF | J_{SC} (mA/cm²) |
|---|---|---|---|---|
| FS | 23.78 | 1.171 | 0.821 | 24.74 |
| RS | 24.37 | 1.171 | 0.840 | 24.78 |

Table 5 below shows averaged photovoltaic device characteristics obtained from 28 samples for each of M1, M2, and M3 structures. The highest average PCE, 23.79%, was confirmed for M3.

TABLE 5

| | V_{OC} (V) | PCE (%) | FF (%) | J_{SC} (mA/cm²) |
|---|---|---|---|---|
| M1 | 1.125 ± 0.018 | 21.69 ± 0.52 | 79.10 ± 1.27 | 24.38 ± 0.12 |
| M2 | 1.035 ± 0.020 | 19.44 ± 0.92 | 75.66 ± 3.40 | 24.83 ± 0.20 |
| M3 | 1.165 ± 0.008 | 23.79 ± 0.31 | 82.70 ± 0.74 | 24.70 ± 0.14 |

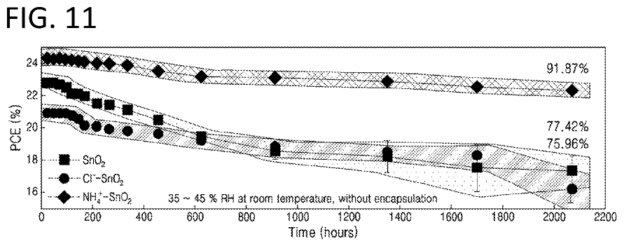

FIG. 11 shows the test results of the long-term stability of the photovoltaic devices M1, M2, and M3. The PCE for M3 remained at 91.87% even after 2,000 hours, confirming excellent long-term stability.

The above description of the present disclosure is provided for the purpose of illustration, and it would be understood by those skilled in the art that various changes and modifications may be made without changing technical conception and essential features of the present disclosure. Thus, it is clear that the above-described examples are illustrative in all aspects and do not limit the present disclosure. For example, each component described to be of a single type can be implemented in a distributed manner. Likewise, components described to be distributed can be implemented in a combined manner.

The scope of the present disclosure is defined by the following claims rather than by the detailed description of the embodiment. It shall be understood that all modifications and embodiments conceived from the meaning and scope of the claims and their equivalents are included in the scope of the present disclosure.

What is claimed is:

1. A perovskite photovoltaic device, comprising:
a first passivation layer including an ammonium salt;
an electron transport layer formed on the first passivation layer and including a metal oxide;
a perovskite layer formed on the electron transport layer; and
a second passivation layer formed on the perovskite layer and including a compound represented by the following Chemical Formula 1,
wherein a two-dimensional perovskite is included at an interface between the electron transport layer and the perovskite layer:[Chemical Formula 1] 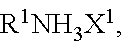
In Chemical Formula 1,
R¹ is a C₅₋₂₀ alkyl group, and
X¹ is F, Cl, Br, or I.

2. The perovskite photovoltaic device of claim 1,
wherein the ammonium salt includes at least one selected from NH₄Cl (ammonium chloride), NH₄Br (ammonium bromide), NH₄I (ammonium iodide), NH₄F (ammonium fluoride), NH₄NO₃ (ammonium nitrate), (NH₄)₂CO₃ (ammonium carbonate), NH₄HCO₃ (ammonium bicarbonate), (NH₄)₂SO₄ (ammonium sulfate), (NH₄)₂S₂O₃(ammonium persulfate), NH₄HSO₃ (ammonium bisulfite), NH₄HSO₄ (ammonium bisulfate), NH₄ClO₄ (ammonium perchlorate), CH₃COONH₄ (ammonium acetate), C₆H₅COONH₄ (ammonium benzoate), NH₄H₂PO₄ (ammonium dihydrogen phosphate), (NH₄)₂HPO₄ (diammonium hydrogen phosphate), NH₄SCN (ammonium thiocyanate), NH₄BF₄ (ammonium tetrafluoroborate), and NH₄PF₆ (ammonium hexafluorophosphate).

3. The perovskite photovoltaic device of claim 1,
wherein the two-dimensional perovskite is formed through self-assembly.

4. The perovskite photovoltaic device of claim 1,
wherein the two-dimensional perovskite includes a compound represented by the following Chemical Formula 3: 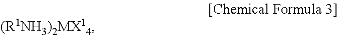
In Chemical Formula 3,
R¹ is a C₅₋₂₀ alkyl group,
M is Pb, Sn, Cu, Ni, Co, Fe, Mn, Pd, Cd, Ge, Cs, Eu, or a combination thereof, and
X¹ is F, Cl, Br, or I.

5. The perovskite photovoltaic device of claim 1,
wherein the two-dimensional perovskite includes OA₂PbI₄.

6. The perovskite photovoltaic device of claim 1,
wherein the metal oxide includes at least one selected from SnO₂, TiO₂, ZnO, WO₃, RuO₂, LaₓSr₁₋ₓCoO₃, LaₓSr₁₋ₓMnO₃, BaSnO₃ and LaNiO₃, and
wherein 0<x<0.5.

7. The perovskite photovoltaic device of claim 5,
wherein a C 1s X-ray photoelectron spectroscopy (XPS) spectrum at the interface between the electron transport layer and the perovskite layer exhibits a peak in the range of 291 eV to 294 eV due to the two-dimensional OA₂PbI₄.

8. The perovskite photovoltaic device of claim 1, further comprising:
a substrate, a first electrode, a hole transport layer, and/or a second electrode.

9. A method of fabricating a perovskite photovoltaic device, comprising:
forming a first passivation layer including an ammonium salt on a first electrode;
forming an electron transport layer including a metal oxide on the first passivation layer;
forming a perovskite layer on the electron transport layer; and
forming a second passivation layer including a compound represented by the following Chemical Formula 1 on the perovskite layer,
wherein a two-dimensional perovskite is self-assembled at an interface between the electron transport layer and the perovskite layer: 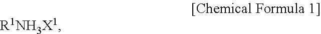
In Chemical Formula 1,
R¹ is a C₅₋₂₀ alkyl group, and
X¹ is F, Cl, Br, or I.

10. The method of claim 9,
wherein the ammonium salt includes at least one selected from NH₄Cl (ammonium chloride), NH₄Br (ammonium bromide), NH₄I (ammonium iodide), NH₄F (ammonium fluoride), NH₄NO₃ (ammonium nitrate), (NH₄)₂CO₃ (ammonium carbonate), NH₄HCO₃ (ammonium bicarbonate), (NH₄)₂SO₄ (ammonium sulfate), (NH₄)₂S₂O₈(ammonium persulfate), NH₄HSO₃ (ammonium bisulfite), NH₄HSO₄ (ammonium bisulfate), NH₄ClO₄ (ammonium perchlorate), CH₃COONH₄ (ammonium acetate), C₆H₅COONH₄ (ammonium benzoate), NH₄H₂PO₄ (ammonium dihydrogen phosphate), (NH₄)₂HPO₄ (diammonium hydrogen phosphate), NH₄SCN (ammonium thiocyanate), NH₄BF₄ (ammonium tetrafluoroborate), and NH₄PF₆ (ammonium hexafluorophosphate).

11. The method of claim 9,
wherein the two-dimensional perovskite includes a compound represented by the following Chemical Formula 3: 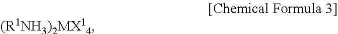
In Chemical Formula 3,
R¹ is a C₅₋₂₀ alkyl group,
M is Pb, Sn, Cu, Ni, Co, Fe, Mn, Pd, Cd, Ge, Cs, Eu, or a combination thereof, and
X¹ is F, Cl, Br, or 1.

12. The method of claim 9,
wherein the metal oxide includes at least one selected from SnO₂, TiO₂, ZnO, WO₃, RuO₂, LaₓSr₁₋ₓCoO₃, LaₓSr₁₋ₓMnO₃, BaSnO₃ and LaNiO₃, and
wherein 0<x≤0.5.

13. The method of claim 9,
wherein the process of forming the first passivation layer includes a process of applying a first passivation solution including the ammonium salt.

14. The method of claim 13,
wherein the concentration of the ammonium salt in the first passivation solution is 1 mM to 1,000 mM.

15. The method of claim 9,
wherein the process of forming the second passivation layer includes a process of applying a second passivation solution including the compound represented by Chemical Formula 1.

16. The method of claim 15,
wherein the concentration of the compound represented by Chemical Formula 1 in the second passivation solution is 1 mM to 1,000 mM.

17. The method of claim 9,
wherein after the first passivation layer, the electron transport layer, and the second passivation layer are formed, each layer is further subjected to UV-ozone treatment.

18. The method of claim 17,
wherein the UV-ozone treatment is performed for 1 minute to 100 minutes.
